(19) United States
(12) Patent Application Publication
(10) Pub. No.: US 2023/0420346 A1
(43) Pub. Date: Dec. 28, 2023

(54) SINGLE LITHOGRAPHY METHODS FOR INTERCONNECT ARCHITECTURES

(71) Applicant: Intel Corporation, Santa Clara, CA (US)

(72) Inventors: Yi Yang, Gilbert, AZ (US); Suddhasattwa Nad, Chandler, AZ (US); Ali Lehaf, Chandler, AZ (US); Jason Steill, Phoenix, AZ (US)

(21) Appl. No.: 17/846,303

(22) Filed: Jun. 22, 2022

(51) Int. Cl. H01L 23/498; H01L 21/48

(52) U.S. Cl. CPC H01L 23/49822; H01L 23/49811; H01L 23/49894; H01L 21/4857; H01L 21/4853

(57) ABSTRACT

Various embodiments disclosed relate to a semiconductor assembly interconnect structure. The present disclosure includes an interconnect structure that case include a substrate, a metallic layer thereon, an adhesion promoter film formed over the metallic layer and forming a flat region over a flat portion of the metallic layer, a solder resist layer formed over the adhesion promoter film, an opening in the solder resist layer and the adhesion promoter film in the flat region of the adhesion promotion film, the opening connecting to the flat portion of the metallic layer, and a stacked electrical connector formed on the metallic layer within the opening. Methods of making an interconnect structure can include patterning a metallic layer on a substrate, depositing an adhesion promoter layer on the metallic layer opposite the substrate, patterning the adhesion promoter layer to expose selected portions of the metallic layer, and depositing a surface finish layer on the exposed selected portions of the metallic layer.

### TECHNICAL FIELD

Embodiments described herein generally relate to semiconductor devices and packaging.

### BACKGROUND

Integrated circuits (ICs) and other electronic components or devices can be packaged on a semiconductor package. Smaller scaling of integrated circuits has allowed a larger number of small features and increased densities of functional components on such semiconductor packages. In some cases, multiple layers of interconnects can be used, such as in multi-die packages, sometimes with embedded components. First layer interconnects (FLI) can be used in such packages to electrically couple components. Manufacturing of such interconnects can be done, for example, with lithography methods.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIGS. 1A-1G illustrate a schematic representation of a single lithography method for making an interconnect in an example.

FIG. 2 illustrates an interconnect made by a single lithography method in an example.

FIG. 3 depicts a method of making an interconnect in an example.

FIG. 4 depicts a schematic of a computer system in an example.

### DETAILED DESCRIPTION

The present disclosure describes, among other things, is a single lithography method for first layer interconnect (FLI) architecture with an embedded silicon nitride film (SiNx). Conventionally, exposed plater-copper regions on FLI printed circuit boards (PCBs) have a surface finish to protect them from oxidation. Such a surface finish can have good solderability and bondability, such as to allow mounting of components and wire bonds on the PCB. The surface finish should also be smooth for connector contact. Some surface finishes can suffer during the existing FLI production flow processes. Such production processes can cause adhesion, plating, and uniformity issues within the FLI that reduces the effectiveness of surface finishes. Discussed here is an alternative, single lithography method of producing FLI using an embedded SiNx film to allow for better surface finish adhesion.

Specifically, exposed plated-copper regions in FLIs on PCBs involve a surface finish to protect the copper therein from oxidation, and to apply a smooth surface for good contact with connectors. High temperatures used during FLI production methods, such as during soldering, can cause surface finish materials to diffuse into the solder, altering mechanical, physical, and electrical properties of solder interconnects. These surface finishes can include, for example, organic solderability preservative (OSP), immersion silver, gold, or tin, electrolytic nickel gold, electroless nickel immersion gold, or combinations thereof.

Some methods of processing an interconnect, such as with a nickel/gold surface finish, can involve a dual lithography step. In such processes, surface copper and nickel/gold can be defined through two consecutive passes of lithography, followed by an adhesion promoter deposition for connections between the nickel/gold surface finish, copper, and/or patterned solder resist.

However, this type of dual lithography process creates several challenges and risks. For example, inaccurate alignment of a second dry film photoresist layer during the second lithography pass can create issues in the semiconductor package. Such inaccurate alignment can cause challenges with the packaging integrity and connectors. In some cases, nickel to dry film photoresist layers can be delaminated over time after the second lithography pass. Moreover, after plating with the surface finish layer, such as during stripping of a second dry film photoresist layer applying during a second lithography pass, there is a risk of residual dry film photoresist layer at corners and other portions of the interconnect, which can result in non-uniform deposition of silicon nitrides and unreliable interfaces within the interconnect. Similalry, during stripping of dry film photoresist layer, nickel in the surface finish layer can be exposed to air, and potentially oxidize the nickel, such as at sidewalls. This can compromise adhesion, and be easily degraded downstream with wet chemicals, causing more delamination risk.

In some processes, such as where copper with a nickel/pladium/gold configuration is used, the thickness of these metals can sum to about 100 nanometers. In this case, coverage requirement for silicon nitride deposition thereon is in such a high aspect ratio feature that it is challenging. In some cases, additional silicon nitride processes can be needed from a sputter (e.g., anisotropic deposition) to a chemical vapor deposition (e.g., isotropic deposition) to accommodate these layer thicknesses. This can add time and cost to the process. Additionally, in a dual lithography process, removal of silicon nitrides can be done by dry etching, but this can etch the surface of a surface finish component, such as gold, which can roughen the surface and negatively impact later contact with connectors.

By comparison, the single lithography methods discussed herein have several advantages, some of which are unexpected. The method can allow for FLI production with better reliability, such as by avoiding misalignment, residuals, or poor coverage on sidewalls, such as can happen by alternating double dry film photoresist layering. Additionally, some surface finishes, such as a nickel-pladium-gold plating layer with SR patterning, can be applied without removal for micro-ball attachment. This can allow for lower risk of exposed nickel at sidewalls, and a lower risk of oxidation. Thus, adhesion between the dry adhesion layer and surface finish on sidewalls can be more reliable. Moreover, a dry adhesion promoter film that is etched before plating with metallics can create a lower risk, such as by not roughening the surface finish layer, allowing for a smoother surface overall and better connector contact.

In an example, a semiconductor assembly can include a semiconductor die and an interconnect. The interconnect can include a substrate, a metallic layer thereon, an adhesion promoter film formed over the metallic layer, a solder resist layer over the adhesion promoter film, and a stacked electrical connector. The adhesion promoter film can form a flat region over a flat portion of the metallic layer. An opening can be formed in the solder resist layer and the adhesion promoter film in the flat region of the adhesion promoter film. The opening can connect to the flat portion of the metallic layer. The stacked electrical connector can be formed in the opening.

In an example, a method of making a first layer interconnect can include patterning a metallic layer on a substrate, depositing an adhesion promoter layer on the metallic layer opposite the substrate, applying a solder resist layer over the adhesion promoter layer, forming an opening through the solder resist layer and the adhesion promoter layer, and depositing a multilayer electrical connector in the opening.

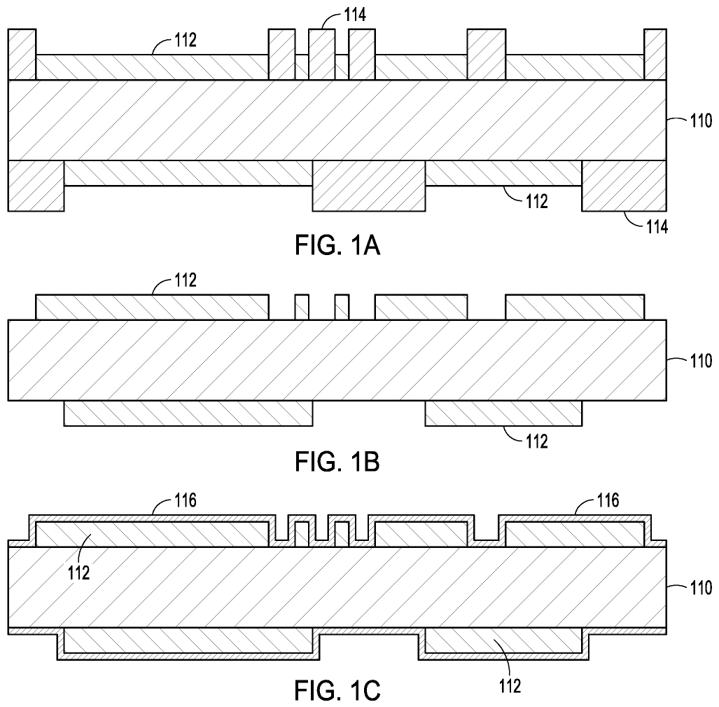

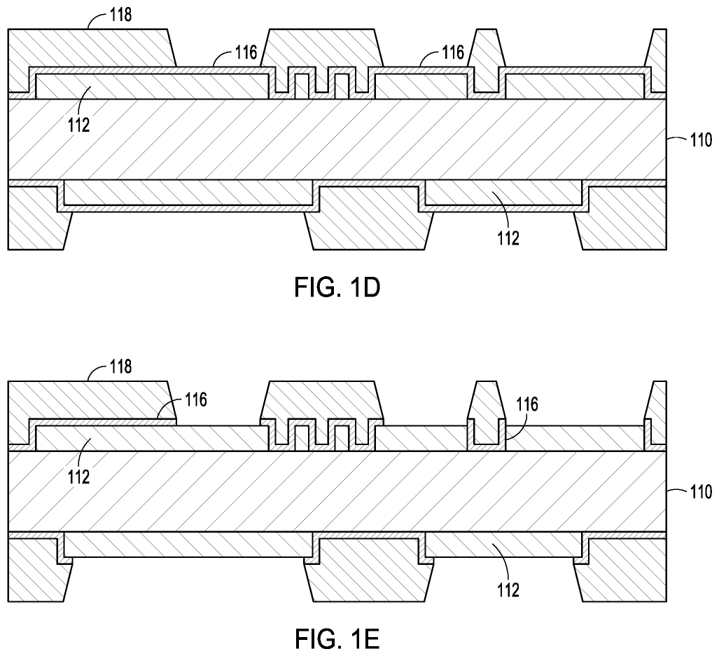

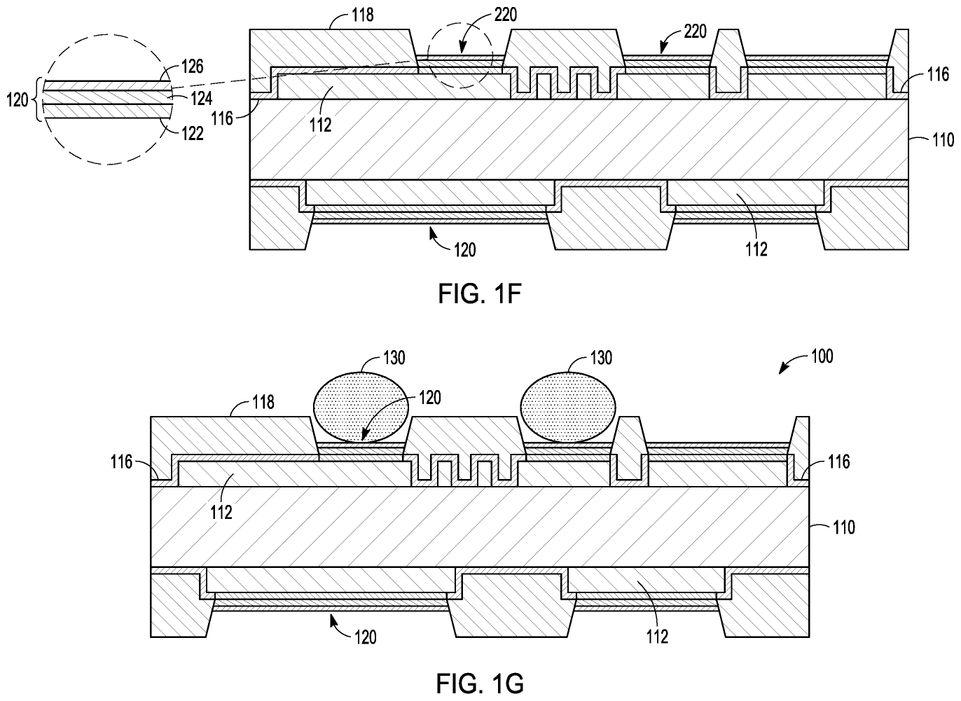

FIGS. 1A to 1G illustrates a schematic representation of a single lithography method for making an interconnect 100 in an example. The method can include a single lithography process flow with embedding of a dry adhesion promoter layer, such as silicon nitride (SiNx) deposition, before surface finish formation to allow for more reliable processing and lower costs. The process can flow from FIG. 1A through FIG. 1G as shown.

The interconnect 100 can include, for example, at various points during the process, a substrate 110, metallic layer 112, dry film photoresist layer 114, adhesion promoter layer 116, solder resist layer 118, surface finish layer 120 including multiple layers 122, 124, 126, and micro-ball array 130. In the method of FIGS. 1A to 1G, instead of defining a surface finish layer 120 right after the metallic layer 112 (as done in double lithography methods), a dry adhesion promoter layer 116 can be deposited, such that the adhesion promoter layer 116 is embedded within the interconnect 100 and helps improve the interconnect assembly integrity.

At FIG. 1A, a lithography step can be done to apply metallic layer 112 over the substrate 110. Here, the dry film photoresist (DFR) layer 114 from the lithography process can be seen on the substrate near the metallic layer 112. The metallic layer 112 can be, for example, a plated metal for electrical connection, such as a copper layer. At FIG. 1B, the DFR layer 114 can be stripped off the assembly, exposing the patterned metallic layer 112, such as plated copper. The metallic layer 112 can include one or more portions that are substantially planar, such as for electrical contacts or pads.

At FIG. 1C, a dry adhesion promoter layer 116 can be applied to the interconnect 100, such as over the metallic layer 112 and the substrate 110. The dry adhesion promoter layer 116 can be, for example, a silicon nitride (SiNx). In embodiments where the dielectric layer is a silicon nitride the dielectric layer will include both silicon and nitrogen atoms. The application of the dry adhesion promoter layer 116 can later (e.g., at FIGS. 1E-1F) be further shaped to allow for openings for the surface finish layer 120. The dry adhesion layer 116 can be applied, for example, by lamination or deposition. The dry adhesion layer 116 can be, for example, a dielectric layer. The dielectric layer can include, for example, silicon and nitrogen. In some cases, the dielectric layer can include more nitrogen than either the substrate or the metal layer. In some cases, if the dielectric is silicon nitride, then the amount of nitrogen detectable can be substantial whereas the metal layer can have have minimal nitrogen, such as from contamination. In various examples, the dielectric layer can have at least twice as much nitrogen as the substrate.

At FIG. 1D, solder resist layer 118 can be applied on top of the dry adhesion layer 116. The solder resist layer 118 can be patterned on the plated copper as desired for the interconnect 100, such as covering particular portions of the interconnect 100. The dry adhesion layer 116 can be embedded between the solder resist layer 118 and the metallic layer 112. The selective application of the solder resist layer 118 on the interconnect 100 can allow for formation of one or more openings above a portion of the metallic layer 112.

At FIG. 1E, particular portions of the adhesion promoter layer 116 can be removed, such as by a selective processes like laser drilling, plasma-based techniques, or dry etching, to reveal the metallic layer 112 contacts, such as above the one or more portions of the metallic layer 112 that are substantially planar. The selective removal of the adhesion promoter layer 116 can allow for deposition of a surface finish and connector assembly in the openings aligned with the one or more substantially planar portions of the metallic layer 112. The dry adhesion layer 116, where still embedded between the solder resist layer 118 and the metallic layer 112, can help create a strong bond therebetween, and help reduce delamination within the interconnect 100.

At FIG. 1F, a multi-layer connector surface finish layer 120 can be produced in the openings where the dry adhesion layer 116 has been selectively removed. The surface finish layer 120 can be, for example, a stacked electrical connector. Such a multi-layer connector surface finish layer 120 can include, for example, layers 122, 124, 126. In an example, the layers can include a first layer 122 of nickel, a second layer 124 of palladium, and a third layer of gold, for a NiPdAu multi-layer connector surface finish layer 120. These layers can be deposited by a variety of methods, such as plating of metallic sub-layers. These layers can be selectively deposited into the openings.

In some cases, the surface finish layer 120 can include organic solderability preservative (OSP), immersion silver, gold, or tin, electrolytic nickel gold, or electroless nickel immersion gold. In some cases, the use of a surface finish layer 120 with gold can allow for good solderability protection and wire bondability, with protection from oxidation, and a substantially planar surface.

At FIG. 1G, one or more micro-ball attachments 130 can be connected to the interconnect 100, such as by a reflow process. Because the surface finish layer 120 is introduced later in the process flow, these is a reduced risk that stripping steps can reduce or change the integrity of the surface finish layer 120, compared to dual lithography method techniques.

Overall, the process shown and discussed with reference to FIGS. 1A to 1G can allow for a reliable flow for surface finish application in first layer interconnect architectures. A dry deposite of a dry adhesion promoter after metallic patterning, followed by solder resist patterning, etching to expose the dry adhesion promoter, and surface finish layer deposition, can allow for FLIs with better alignment, lower delamination, better residuals, and other advantages.

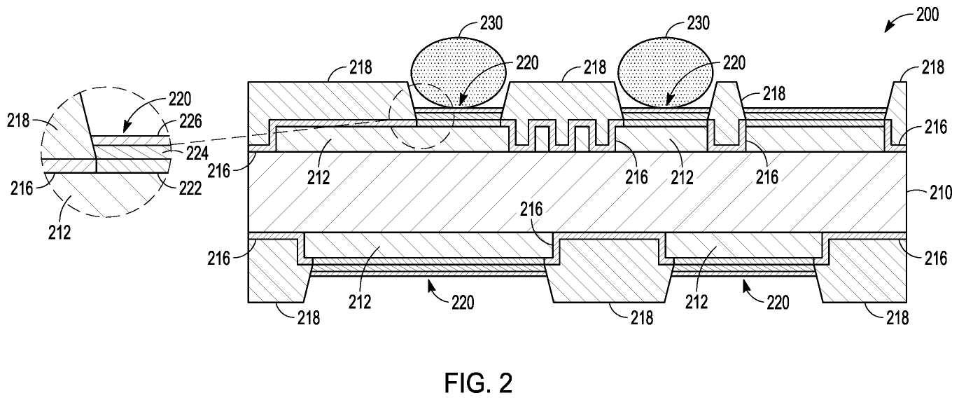

FIG. 2 illustrates an interconnect 200 made by a single lithography method in an example. The interconnect 200 can include, for example, a substrate 210, metallic layer 212, adhesion promoter layer 216, solder resist patterning 218, surface finish 220 including layers 222, 224, 226, and micro ball array 230.

The substrate 210 can be a based layer for the interconnect 200. The substrate 210 can be, for example, a silicon layer for hosting a variety of interconnections. The interconnect 200 can be, for example, a first layer interconnect (FLI), such as for an embedded bridge die or other semiconductor assembly. In some cases, such an FLI can be used to electrically connect one or more components within a semiconductor assembly, such as integrated circuits (ICs), semiconductor dies, processor dies, memory dies, input or output (I/O) channels, or other electrical components.

The metallic layer 212 can be a layer used for creating such connections within the interconnect 200. For example, the metallic layer 212 can be a plated copper layer, that has at least some portions that are substantially planar, such as for pads or other connective traces.

The adhesion promoter layer 216 can be a dry adhesion promoter layer, such as a silicon nitride layer. The solder resist patterning 218 can be, for example, an insulating ink that helps cover and protect various portions of the interconnect 200.

The surface finish 220 including layers 222, 224, 226, can be a multi-layer connector extending from the interconnect 200 metallic layer 212 for electrical connection with one or more other electrical components. In an example, the layers can include a first layer 122 of nickel, a second layer 124 of palladium, and a third layer of gold, for a NiPdAu multi-layer connector surface finish layer 120. In some cases, the surface finish layer 120 can include organic solderability preservative (OSP), immersion silver, gold, or tin, electrolytic nickel gold, or electroless nickel immersion gold.

The micro ball array 230 can include one or more micro balls connected to the surface finish 220 to electrically couple the interconnect 200 to one or more other electrical components. The interconnect 200 can have a unique profile with the placement of the dry adhesion promoter layer 216 within the interconnect 200.

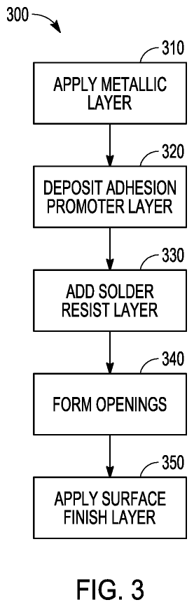

FIG. 3 depicts a method 300 of making an interconnect in an example. The method 300 can include blocks 310 to 350.

At block 310, a metallic layer can be patterned onto a substrate. For example, a copper layer can be plated onto a silicon substrate. The metallic layer can have one or more substantially planar or flat portions. In some cases, this can be done through lithography. In some cases, removal of a dry film photoresist layer can be done at this step.

At block 320, an adhesion promoter layer can be deposited on the metallic layer. The adhesion promoter layer can, for example, be deposited directly over the metallic layer. This adhesion promoter layer can, for example, be a dry layer. At block 330, a solder resist layer can be situated over the adhesion promoter layer.

At block 340, one or more openings can be formed through the solder resist layer and the dry adhesion promoter layer to the metallic layer, such as at the substantially planar portions of the metallic layer.

At block 350, a surface finish layer, such as including a multi-layer electrical connector, can be formed in the one or more openings. The multi-layer electrical connector can, for example, include a nickel-palladium-gold connector.

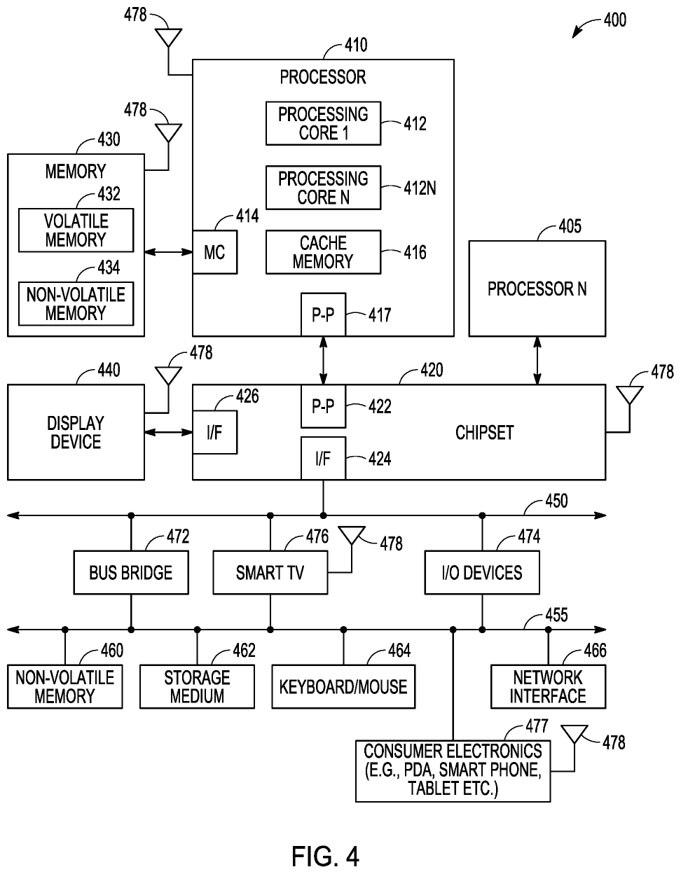

FIG. 4 depicts a schematic of a computer system in an example. FIG. 4 illustrates a system level diagram, depicting an example of an electronic device (e.g., system) that may include an interposer and/or methods described above. In one embodiment, system 400 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 400 includes a system on a chip (SOC) system.

In one embodiment, processor 410 has one or more processor cores 412 and 412N, where 412N represents the Nth processor core inside processor 410 where N is a positive integer. In one embodiment, system 400 includes multiple processors including 410 and 405, where processor 405 has logic similar or identical to the logic of processor 410. In some embodiments, processing core 412 includes, but is not limited to, pre-fetch logic to fetch instructions, decode logic to decode the instructions, execution logic to execute instructions and the like. In some embodiments, processor 410 has a cache memory 416 to cache instructions and/or data for system 400. Cache memory 416 may be organized into a hierarchal structure including one or more levels of cache memory.

In some embodiments, processor 410 includes a memory controller 414, which is operable to perform functions that enable the processor 410 to access and communicate with memory 430 that includes a volatile memory 432 and/or a non-volatile memory 434. In some embodiments, processor 410 is coupled with memory 430 and chipset 420. Processor 410 may also be coupled to a wireless antenna 478 to communicate with any device configured to transmit and/or receive wireless signals. In one embodiment, an interface for wireless antenna 478 operates in accordance with, but is not limited to, the IEEE 802.11 standard and its related family, Home Plug AV (HPAV), Ultra Wide Band (UWB), Bluetooth, WiMAXs, or any form of wireless communication protocol.

In some embodiments, volatile memory 432 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 434 includes, but is not limited to, flash memory, phase change memory (PCM), read-only memory (ROM), electrically erasable programmable read-only memory (EEPROM), or any other type of non-volatile memory device.

Memory 430 stores information and instructions to be executed by processor 410. In one embodiment, memory 430 may also store temporary variables or other intermediate information while processor 410 is executing instructions. In the illustrated embodiment, chipset 420 connects with processor 410 via Point-to-Point (PtP or P-P) interfaces 417 and 422. Chipset 420 enables processor 410 to connect to other elements in system 400. In some embodiments of the example system, interfaces 417 and 422 operate in accordance with a PtP communication protocol such as the Intel® QuickPath Interconnect (QPI) or the like. In other embodiments, a different interconnect may be used.

In some embodiments, chipset 420 is operable to communicate with processor 410, 405N, display device 440, and other devices, including a bus bridge 472, a smart TV 476, I/O devices 474, nonvolatile memory 460, a storage medium (such as one or more mass storage devices) 462, a keyboard/mouse 464, a network interface 466, and various forms of consumer electronics 477 (such as a PDA, smart phone, tablet etc.), etc. In one embodiment, chipset 420 couples with these devices through an interface 424. Chipset 420 may also be coupled to a wireless antenna 478 to communicate with any device configured to transmit and/or receive wireless signals. In one example, any combination of components in a chipset may be separated by a continuous flexible shield as described in the present disclosure.

Chipset 420 connects to display device 440 via interface 426. Display 440 may be, for example, a liquid crystal display (LCD), a light emitting diode (LED) array, an organic light emitting diode (OLED) array, or any other form of visual display device. In some embodiments of the example system, processor 410 and chipset 420 are merged into a single SOC. In addition, chipset 420 connects to one or more buses 450 and 455 that interconnect various system elements, such as I/O devices 474, nonvolatile memory 460, storage medium 462, a keyboard/mouse 464, and network interface 466. Buses 450 and 455 may be interconnected together via a bus bridge 472.

In one embodiment, mass storage device 462 includes, but is not limited to, a solid state drive, a hard disk drive, a universal serial bus flash memory drive, or any other form of computer data storage medium. In one embodiment, network interface 466 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMAX, or any form of wireless communication protocol.

While the modules shown in FIG. 4 are depicted as separate blocks within the system 400, the functions performed by some of these blocks may be integrated within a single semiconductor circuit or may be implemented using two or more separate integrated circuits. For example, although cache memory 416 is depicted as a separate block within processor 410, cache memory 416 (or selected aspects of 416) can be incorporated into processor core 412.

### Various Notes & Examples

Example 1 is a semiconductor assembly comprising: a semiconductor die; an interconnect structure on an active side of the semiconductor die comprising: a substrate; a metallic layer thereon; an adhesion promoter film formed over the metallic layer and forming a flat region over a flat portion of the metallic layer; a solder resist layer formed over the adhesion promoter film; an opening in the solder resist layer and the adhesion promoter film in the flat region of the adhesion promotion film, the opening connecting to the flat portion of the metallic layer; and a stacked electrical connector formed on the metallic layer within the opening.

In Example 2, the subject matter of Example 1 optionally includes wherein the interconnect structure comprises a first layer interconnect structure.

In Example 3, the subject matter of any one or more of Examples 1-2 optionally include wherein the adhesion promoter film comprises a silicon nitride.

In Example 4, the subject matter of any one or more of Examples 1-3 optionally include wherein the metallic layer comprises copper.

In Example 5, the subject matter of any one or more of Examples 1-4 optionally include wherein the die comprises a processor die.

In Example 6, the subject matter of any one or more of Examples 1-5 optionally include wherein the die comprises a memory die.

In Example 7, the subject matter of any one or more of Examples 1-6 optionally include a plated layer on the surface finish layer.

In Example 8, the subject matter of any one or more of Examples 1-7 optionally include a component connected to the semiconductor die through the interconnect structure.

In Example 9, the subject matter of Example 8 optionally includes wherein the component comprises an I/O component.

Example 10 is a semiconductor assembly interconnect structure, made by the method of: patterning a metallic layer on a substrate; depositing an adhesion promoter layer on the metallic layer opposite the substrate; applying a solder resist layer over the adhesion promoter layer; forming an opening through the solder resist layer and the adhesion promoter layer; and depositing a multilayer electrical connector in the opening.

In Example 11, the subject matter of Example 10 optionally includes attaching one or more components to the interconnect structure.

Example 12 is a method of making a semiconductor device, the method comprising: patterning a metallic layer on a substrate; depositing an adhesion promoter layer on the metallic layer opposite the substrate; patterning the adhesion promoter layer to expose selected portions of the metallic layer; and depositing a surface finish layer on the exposed selected portions of the metallic layer.

In Example 13, the subject matter of Example 12 optionally includes wherein patterning a metallic layer comprises planographic printing.

In Example 14, the subject matter of Example 13 optionally includes wherein patterning a metallic layer comprises lithography.

In Example 15, the subject matter of any one or more of Examples 12-14 optionally include wherein patterning a metallic layer on a substrate comprises a single pass.

In Example 16, the subject matter of any one or more of Examples 12-15 optionally include wherein the adhesion promoter layer comprises a dry adhesion promoter.

In Example 17, the subject matter of Example 16 optionally includes wherein the adhesion promoter layer comprises one or more silicon nitrides.

In Example 18, the subject matter of any one or more of Examples 12-17 optionally include attaching one or more micro-balls to the surface finish layer.

In Example 19, the subject matter of any one or more of Examples 12-18 optionally include plating a second metallic layer on the adhesion promoter layer.

In Example 20, the subject matter of Example 19 optionally includes wherein the second metallic layer comprises nickel, palladium, gold, or combinations thereof.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor assembly comprising:
a semiconductor die; and
an interconnect structure on the semiconductor die comprising:
a substrate;
a metallic layer thereon;
a dielectric layer over the metallic layer and forming a flat region over a flat portion of the metallic layer;
a solder resist layer over the dielectric layer;
an opening in the solder resist layer and the dielectric layer in the flat region of the dielectric layer, the opening connecting to the flat portion of the metallic layer; and
a stacked electrical connector on the metallic layer within the opening.

2. The semiconductor assembly of claim 1, wherein the interconnect structure comprises a first layer interconnect structure.

3. The semiconductor assembly of claim 1, wherein the dielectric layer comprises silicon and nitrogen.

4. The semiconductor assembly of claim 1, wherein the metallic layer comprises copper.

5. The semiconductor assembly of claim 3, wherein the substrate comprises nitrogen, and wherein the dielectric layer comprises at least twice as much nitrogen as the substrate.

6. The semiconductor assembly of claim 1, wherein the die comprises a processor die or a memory die.

7. The semiconductor assembly of claim 1, further comprising a plated layer on the stacked electrical connector.

8. The semiconductor assembly of claim 1, further comprising a component connected to the semiconductor die through the interconnect structure.

9. The semiconductor assembly of claim 8, wherein the component comprises an I/O component.

10. A semiconductor assembly interconnect structure, made by the method of:
patterning a metallic layer on a substrate;
depositing an adhesion promoter layer on the metallic layer opposite the substrate;
applying a solder resist layer over the adhesion promoter layer;
forming an opening through the solder resist layer and the adhesion promoter layer; and
depositing a multilayer electrical connector in the opening.

11. The semiconductor assembly of claim 10, further comprising attaching one or more components to the interconnect structure.

12. A method of making a semiconductor device, the method comprising:
patterning a metallic layer on a substrate;
depositing an adhesion promoter layer on the metallic layer opposite the substrate;
patterning the adhesion promoter layer to expose selected portions of the metallic layer; and
depositing a surface finish layer on the exposed selected portions of the metallic layer.

13. The method of claim 12, wherein patterning a metallic layer comprises planographic printing.

14. The method of claim 13, wherein patterning a metallic layer comprises lithography.

15. The method of claim 12, wherein patterning a metallic layer on a substrate comprises a single pass.

16. The method of claim 12, wherein the adhesion promoter layer comprises a dry adhesion promoter.

17. The method of claim 16, wherein the adhesion promoter layer comprises one or more silicon nitrides.

18. The method of claim 12, further comprising attaching one or more micro-balls to the surface finish layer.

19. The method of claim 12, further comprising plating a second metallic layer on the adhesion promoter layer.

20. The method of claim 19, wherein the second metallic layer comprises nickel, palladium, gold, or combinations thereof.
